(19) United States
(12) Patent Application Publication
(10) Pub. No.: US 2008/0251907 A1
(43) Pub. Date: Oct. 16, 2008

(54) Electronic Device With Stress Relief Element

(75) Inventors: Soenke Habenicht, Hamburg (DE); Ansgar Thorns, Hamburg (DE); Heinrich Zeile, Hamburg (DE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: Koninklijke Philips Electronics N.V., Eindhoven (NL)

(21) Appl. No.: 10/591,356

(22) PCT Filed: Mar. 3, 2005
(86) PCT No.: PCT/IB05/50777

§ 371 Date: Aug. 15, 2007

Related U.S. Application Data
(60) Provisional application No. 60/550,406, filed on Mar. 5, 2004.

(51) Int. Cl. H01L 23/04

(52) U.S. Cl. 257/690; 257/E23.181

(57) ABSTRACT

The present invention relates to an electronic device whose component body contains at least one stress relief element (4), a substrate (1) with an upper surface and side walls at least one circuit element (2) located on said substrate (1) and at least one passivation and/or isolating layer (3) placed on said substrate (1), whereby said isolating layer (3) covers said at least one circuit element (2) and/or said substrate (1) and contains
a top surface,
at least one outer side surface which is located towards a side wall of said substrate and
at least one outer edge, which is formed by said top surface and said at least one outer side surface,
   characterized in that at least one stress relief element (4) is made out of a ductile material and simultaneously
a) covers the top surface of said passivation and/or isolating layer (3); and
b) overlaps said outer edge of said passivation and/or isolating layer (3); and
c) extends along said outer surface of said passivation and/or isolating layer (3); and
d1) contacts the upper surface of the substrate (1) or
d2) forms a bridge with at least one circuit element (2) in that way that the stress relief element is linked with the upper surface of the substrate (1) via at least one circuit element (2).

The present invention relates to an electronic device whose component body contains a substrate and circuit elements placed on said substrate

Electronic devices, e.g. semiconductor chips, who comprise a substrate and circuit elements placed on said substrate usually need to be protected, amongst other things against moisture. This is usually achieved by covering these devices with one or more passivation and/or isolating layers, which can be made e.g. out of silicon dioxide or silicon nitride. Finally the electronic device is covered with a covering member, which is in most applications made out of a synthetic resin.

However, the thermal expansion of the covering member is usually up to a factor of 10 different to that of the substrate. Therefore, due to temperature changes e.g. during the operation of the electronic device, there is the danger of introducing lateral stress into the electronic device. This lateral stress is, however, to be avoided, since it may cause malfunction or even destruction of the electronic device. There is even the danger, that lateral stress may cause cracks or disruptions in the electronic device. These cracks or disruptions may then prolong and extend themselves along the electronic device, thus causing malfunction of the electronic device due to:
short circuits (by material that can impinge via these cracks into the electronic device) and/or
introduction of moisture and contaminants or impurities.

The WO 02/09179 A1 of Cutter, which is hereby fully incorporated by reference, disclosed a resin sealed semiconductor device with stress-reducing layer. According to the WO 02 09179, thermal cycling can lead to damaging stress at the upper surface of a semiconductor device chip encapsulated in synthetic resin material, particularly in the case of power devices that include an IC. The WO 02/09179 provides a thick ductile layer pattern of, for example, aluminium over most of the top surface of the insulating over-layer of the chip. Electrically-isolated parts of this ductile covering are individually connected to respective underlying conductive areas so as to reduce charging effects across the insulating over-layer. A sufficient spacing Z1 is present between these isolated parts to avoid short circuits as a result of deformation by shearing and smearing during thermal cycling of the device. The ductile metal layer pattern reduces stress between the insulating material and the plastic material, but it can be both easily and cheaply applied in device manufacture before dividing the wafer into individual chips.

The WO 02/097868 to Schnitt and Fock, which is hereby fully incorporated by reference, discloses an integrated circuit whose component body contains a substrate, circuit elements, interconnection elements, a passivation layer and a fringe segment of a ductile material, wherein the base surface of the component body is formed essentially by the substrate, the cover surface of the component body is formed essentially by the passivation layer and the fringe segment, and the side walls of the component body are formed by the substrate and the fringe segment.

However, this prior art is not able to solve the problem addressed in the present invention.

It is therefore an objective of the present invention to provide a stress relief element which is capable of overcoming the above-mentioned drawbacks and able to reduce essentially, if not totally, lateral stress in an electronic device as described.

This objective is solved by an electronic device as taught by claim 1 of the present invention. Accordingly, an electronic device is provided whose component body contains at least one stress relief element, a substrate with an upper surface and side walls, at least one circuit element located on said substrate and at least one passivation and/or isolating layer placed on said substrate, whereby said isolating layer covers said at least one circuit element and/or said substrate and contains
a top surface,
at least one outer side surface which is located towards a side wall of said substrate and
at least one outer edge, which is formed by said top surface and said at least one outer side surface,
   characterized in that the at least one stress relief element is made out of a ductile material and simultaneously
a) covers the top surface of said passivation and/or isolating layer; and
b) overlaps said outer edge of said passivation and/or isolating layer; and
c) extends along said outer side surface of said passivation and/or isolating layer; and
d1) contacts the upper surface of the substrate or
d2) forms a bridge with at least one circuit element in that way that the stress relief element is linked with the upper surface of the substrate via at least one circuit element

“Forming a bridge” in the sense of the present invention means in particular that a part of the stress relief element covers at least one circuit element resulting in a mechanical and electrical interconnection via this circuit element between the substrate and the stress relief element.

The inventors have studied the problems and dangers concerning lateral stress in electronic devices such as semiconductor chips and integrated circuits and have found the following features for a stress relief element to be essential:

a) The stress relief element must be made out of a ductile material, since only ductile materials are able to actually reduce lateral stress in electronic devices as described above. In case that forces are conducted on the electronic device, e.g. due to temperature changes, these forces are absorbed by the ductile material, which is then partially deformed. The other components of the electronic device remain unchanged.

b) The stress relief element must cover the top surface of said passivation and/or isolating layer, overlap said outer edge of said passivation and/or isolating layer, extend along said outer side surface of said passivation and/or isolating layer; and either contact the upper surface of the substrate or form a bridge with at least one circuit element in that way that the stress relief element is linked with the upper surface of the substrate via at least one circuit element. By doing so, the passivation and/or isolating layer, which is in a sense “protected” by the stress relief element, is prohibited from cracking, which may otherwise occur due to its rather high rigidity as compared to the stress relief element. Therefore, lateral forces are kept from entering the electronic device and cracks or disruptions are prohibited.

According to a preferred embodiment of the present invention, the at least one stress relief element is formed as a sealing ring. A sealing ring in the sense of the present invention means in particular, that the stress relief element extends itself along at least two, preferably three or four side walls of the substrate, thus forming a ring-like structure. By doing so, a protection of the elements inside the sealing ring can be effectively achieved.

According to a preferred embodiment of the present invention, the bridge formed by said stress relief element and at least one circuit member extends itself along said outer side surface of said passivation and/or isolating layer. By doing so, the introduction of lateral forces is prohibited more effectively.

According to a preferred embodiment of the present invention, said stress relief element covers the top surface of said passivation and/or isolating layer, and/or overlaps said outer edge of said passivation and/or isolating layer and/or extends along said outer side surface of said passivation and/or isolating layer in an amount of ≧70%, preferably ≧80% and ≦90%. Thus the protection of the passivation and/or isolating layer is furthermore enhanced.

According to a preferred embodiment of the present invention, the passivation and/or isolating layer is the passivation and/or isolating layer which is located closest to at least one side wall of said substrate. By doing so, nearly all passivation and/or isolating layers which are located on the substrate are effectively protected.

According to a preferred embodiment of the present invention, the electronic device has at least one stress relief element locally and/or electrically isolated from said first stress relief element. By doing so, also the elements located furthermore inside the electronic element can be protected and addressed separately. In a furthermore preferred embodiment, the various stress relief elements may serve as electrical component, e.g. as Bond pads.

According to a preferred embodiment of the present invention, the material of said stress relief element is selected out of a group consisting essentially of aluminium, aluminium alloys, preferably with Si and/or Cu, Copper, Lead, Silver, Gold or mixtures thereof. These materials have proven themselves to be most suitable.

According to a preferred embodiment of the present invention, the tensile strength of said passivation and/or isolating layer is higher than the tensile strength of said stress relief element. If the stress relief element has a lower tensile strength than the passivation and/or isolating layer, it will effectively protect the passivation and/or isolating layer from cracking or disrupting.

According to a preferred embodiment of the present invention, the tensile strength of said passivation and/or isolating layer (3) is ≧1×10⁸ and ≦1×10⁹ Pa. Furthermore, according to a preferred embodiment of the present invention, the tensile strength of said stress relief element (4) is ≧1×10⁷ and ≦1×10⁸ Pa. Materials with such tensile strengths have proven themselves to be most suitable to be used within the present invention.

The present invention as described above has the following advantages over the state of the art:
Since a greater part of the surface of the substrate may be used, the electronic device has a higher potential per size and allows a wider range of applications per given surface area
The invention as described does not require additional coating technologies such as wafer-coating or chip coating. Instead, usual metal deposition technique may be used, thus allowing greater degrees of freedom for the fabrication of the electronic device
The invention as described allows a greater range of plastic materials to be used as isolation and/or passivation materials.

The aforementioned components, as well as the claimed components and the components to be used in accordance with the invention in the described embodiments, are not subject to any special exceptions with respect to their size, shape, material selection and technical concept such that the selection criteria known in the pertinent field can be applied without limitations.

Additional details, characteristics and advantages of the object of the invention are disclosed in the subclaims and the following description of the respective figures—which in an exemplary fashion—show preferred embodiments of the electronic device according to the present invention.

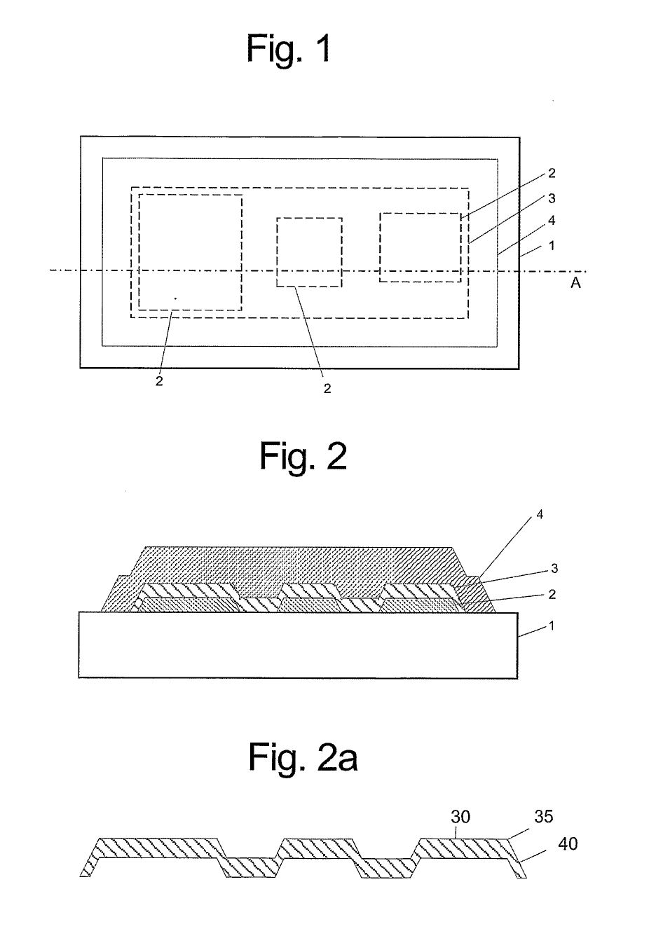

FIG. 1 shows a schematic plan view of an electronic device according to one first embodiment of the present invention,

FIG. 2 shows a cross-sectional view along line A in FIG. 1

FIG. 2a shows a detailed view of the passivation and/or isolating layer of FIG. 2.

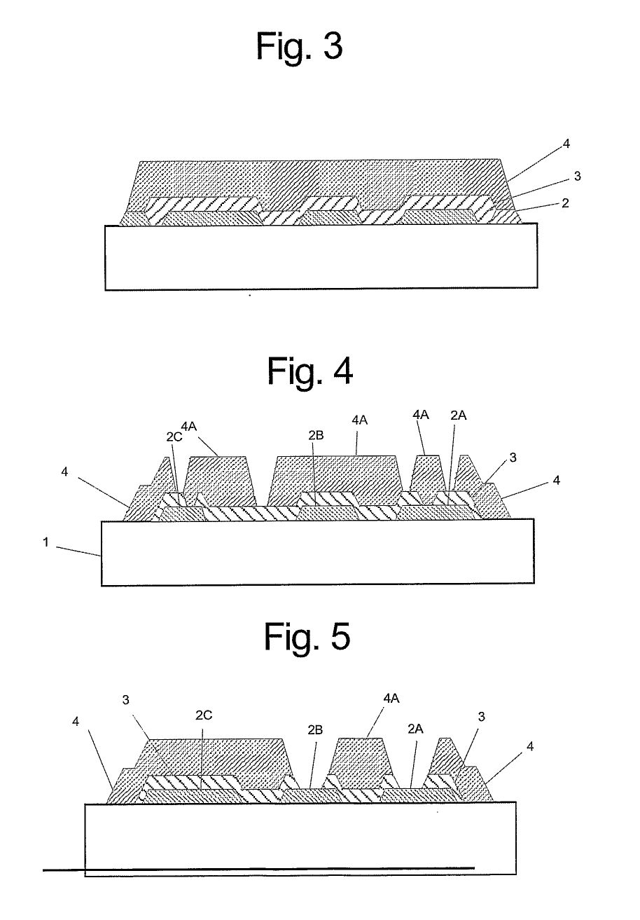

FIG. 3 shows a cross-sectional view of an electronic device according to a second embodiment of the present invention

FIG. 4 shows a cross-sectional view of an electronic device according to a third embodiment of the present invention

FIG. 5 shows a cross-sectional view of an electronic device according to a fourth embodiment of the present invention

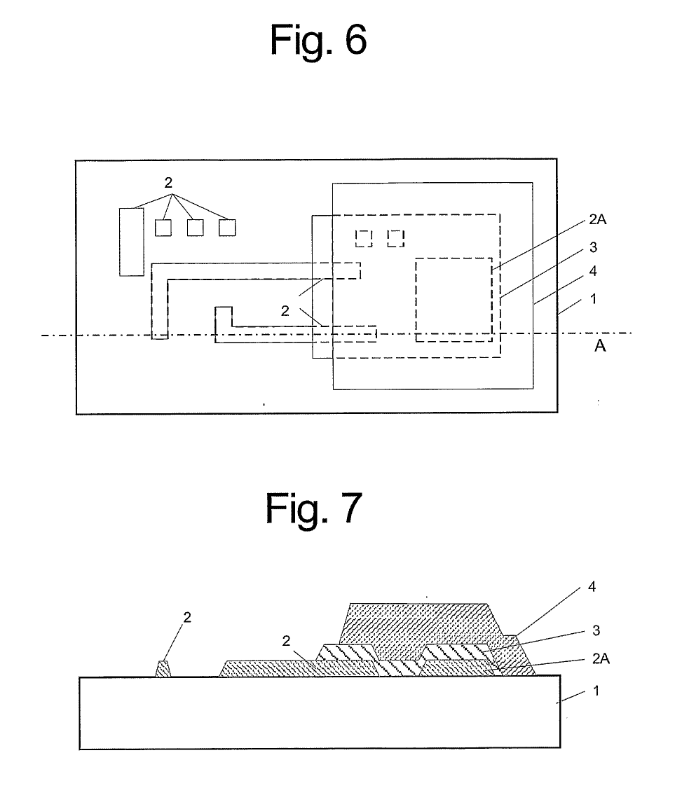

FIG. 6 shows a schematic plan view of an electronic device according to a fifth embodiment of the present invention, and

FIG. 7 shows a cross-sectional view along line A in FIG. 6

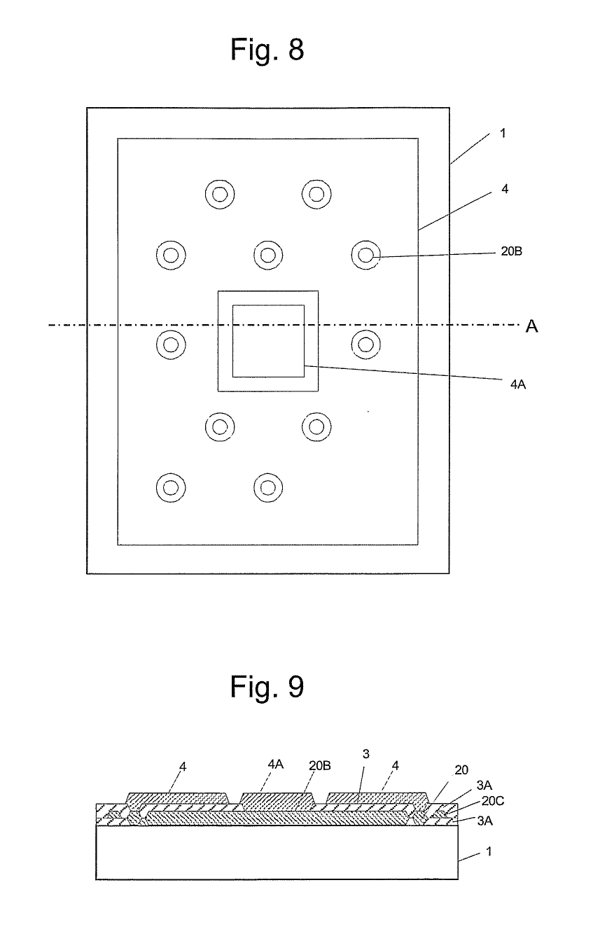

FIG. 8 shows a schematic plan view of an electronic device according to a sixth embodiment of the present invention, and

FIG. 9 shows a cross-sectional view along line A in FIG. 8

FIG. 1 shows a schematic plan view of an electronic device according to one first embodiment of the present invention, FIG. 2 shows a cross-sectional view along line A. FIG. 2a shows a detailed view of the passivation and/or isolating layer of FIG. 2.

As can be seen from FIG. 1 and 2, three circuit elements 2 are located on the substrate 1 of the electronic device, covered by one passivation and/or isolating layer 3. This passivation and/or isolating layer contains a top surface 30, a outer side surface 40 and an outer edge 35 in between. As can be seen from FIG. 2, the stress relief element 4 covers the outer side surface 30, overlaps the outer edge 35, extends itself along the outer side surface 40 and contacts the upper surface of the substrate 1.

FIGS. 3, 4 and 5 show cross-sectional views of an electronic device according to a second third and fourth embodiment of the present invention. In the second embodiment as shown in FIG. 3, the stress relief element 4 forms a bridge with one circuit element 2 so as to link the stress relief element with the upper surface of the substrate 1 via this circuit element 2. This is also an effective way to prohibit the introduction of lateral stress into the electronic device, particularly to the passivation and/or isolating layer 3.

In the embodiments according to FIGS. 4 and 5, there are several stress relief elements 4, 4A present, of which the stress relief elements 4A serve as additional stress relief elements to the inventive stress relief elements 4 and are locally and electrically isolated from each other. By doing so, the several circuit elements 2A, 2B and 2C can be addressed separately from each other.

FIG. 6 shows a schematic plan view of an electronic device according to a forth embodiment of the present invention, and FIG. 7 shows a cross-sectional view along line A in FIG. 6. As can be seen from FIG. 7, it is not necessary for the passivation and/or isolating layer 3 to be covered totally by the stress relief element 4. For the prevention of introduction of lateral stress it may also be sufficient if the side of the passivation and/or isolating layer 3 which is located towards the inner area of the surface is uncovered.

FIG. 8 shows a schematic plan view of an electronic device according to a sixth embodiment of the present invention, and FIG. 9 shows a cross-sectional view along line A in FIG. 8. As can be seen from FIG. 8, the stress relief element 4 is formed as a sealing ring, which extents itself along all four sides of the surface 1. However, it may be sufficient for some applications, if the stress relief element 4 extends itself only along three or even only two sides of the surface and nevertheless form out a kind of ring-like structure. The stress relief element 4 has certain gaps or openings, through which some of the circuit elements 20B may be addressed.

It should be noted, that in this embodiment, the circuit elements 20 are simply metal layers, whereas in the embodiments as shown in FIGS. 1 to 7 the circuit elements 2 may also be more complex. However, all kinds of circuit elements known in the field may be used within the present invention.

Inside the first stress relief element 4, there is a second stress relief element 4A isolated from the first one 4. This second stress relief element may also be addressed separately from the first one 4.

As can be seen from FIG. 9, the stress relief element 4 covers the passivation and/or isolating layer 3, thereby preventing lateral stress or forces to enter the inner area of the electronic device. However, it should be noted that in this embodiment there are two further passivation and/or isolating layers 3a which surround a circuit element 20C. For the present invention it is in some applications not necessary to cover the passivation and/or isolating layer which is located next to the surface side walls. Depending on the nature of the application and the topology of the electronic device, it maybe sufficient for the prevention of lateral stress into the electronic device and especially for the prevention of short circuits, if only certain isolating and/or passivating layers, in this case the isolating and/or passivating layer 3 is covered. Further isolating and/or passivating layers 3a maybe exposed to the outside without deterioration or malfunction of the electronic device.

1. A semiconductor device comprising a semiconductor device body encapsulated in an envelope of synthetic resin material, wherein an insulating layer is present at one surface of the body, a pattern of conductive connections is present on the insulating layer and at windows in the insulating layer, an over-layer of insulating material is present on the pattern of conductive connections, and a layer pattern of ductile metal covers at least most of the surface area of the over-layer of insulating material to provide an interface with the synthetic resin material that reduces stress between the insulating material and the synthetic resin material during thermal cycling of the device, and wherein the ductile metal layer pattern comprises distinct parts that are electrically isolated and spaced from each other on the over-layer, the ductile metal is sufficiently ductile as to deform laterally on the over-layer during thermal cycling of the device, and the spacing of the electrically-isolated parts is sufficient to avoid a short circuit between the electrically-isolated parts as a result of the lateral deformation.

2. A device as claimed in claim 1, wherein the spacing of the electrically-isolated parts of the ductile metal layer pattern is at least 15 micrometres in the device before thermal cycling.

3. A device as claimed in claim 1 or claim 2, wherein the device body comprises integrated circuitry, and at least one of the electrically-isolated parts of the ductile metal layer pattern extends over the over-layer over conductive connections of the integrated circuitry.

4. A device as claimed in any one of claims 1 to 3, wherein the device body comprises integrated circuitry that includes a capacitor, a window is present in the over-layer at the area of the capacitor where a part of the pattern of conductive connections forms an upper plate of the capacitor, and at least one of the electrically-isolated parts of the ductile metal layer pattern extends on the upper plate of the capacitor at the window in the over-layer.

5. A device as claimed in any one of claims 1 to 4, wherein a number of the electrically-isolated parts of the ductile metal layer pattern form metal bond pads that are connected to the conductive connections at windows in the over-layer, and terminal conductors of the device are connected to the metal bond pads.

6. A device as claimed in any one of the preceding claims, wherein at least one part of the ductile metal layer pattern is connected to the same potential as an underlying conductive area.

7. A device as claimed in claim 6, wherein distincts parts of the ductile metal layer pattern that are electrically isolated from each other are individually connected to respective underlying conductive areas.

8. A device as claimed in claim 7, wherein the device body comprises a power-dissipating portion and an integrated circuit portion, a part of the ductile metal layer pattern overlies the power-dissipating portion and is connected to an underlying conductive area of the power-dissipating portion, and at least one other part of the ductile metal layer pattern overlies the integrated circuit portion and is connected to an underlying conductive area of the integrated circuit portion.

9. A device as claimed in any one of the preceding claims, wherein the device body comprises a perimeter termination structure in the vicinity of the periphery of the device body, and a part of the ductile metal layer pattern extends over the termination structure while being spaced from the periphery of the device body.

10. A device as claimed in claim 9, wherein a part of the pattern of conductive connections extends between the termination scheme and the overlying part of the ductile metal layer pattern to screen electrically the termination scheme from the overlying part of the ductile metal layer pattern.

11. A device as claimed in any one of the preceding claims, wherein the ductile metal layer pattern covers at least 90% of the surface area of the over-layer of insulating material.

12. A device as claimed in any one of the preceding claims, wherein the ductile metal layer pattern has a thickness of at least 2.5 micrometres.

13. A device as claimed in any one of the preceding claims, wherein the ductile metal layer is aluminium or an aluminium alloy.
